(19) United States
(12) Patent Application Publication
(10) Pub. No.: US 2008/0110748 A1
(43) Pub. Date: May 15, 2008

(54) Selective High Dielectric Constant Material Etchant

(76) Inventor: John Starzynski, Brooklyn Park, MN (US)

Correspondence Address: Scott Jacobson;Honeywell International Inc., 101 Columbia Road, Morristown, NJ, 07962, US

(21) Appl. No.: 11/662,245

(22) PCT Filed: Mar. 18, 2005
(86) PCT No.: PCT/US05/09172

§ 371 Date: Mar. 8, 2007

Related U.S. Application Data
(63) Continuation-in-part of application No. 10/938,191, filed on Sep. 10, 2004, now abandoned.

(51) Int. Cl. C09K 13/08; C09K 13/04; C09K 13/06; C09K 13/00; B44C 1/22; C23C 14/00

(52) U.S. Cl. 204/192.35; 252/79.1; 252/79.3; 252/79.2; 252/79.4; 216/109

(57) ABSTRACT

Etchants for selective removal of high dielectric constant materials are described herein that comprise at least one fluorin-based constituent; water and at least one solvent or solvent mixture. Methods are also described herein for producing a wet etching chemistry solution that include providing at least one fluorine-based constituent, providing water, providing at least one solvent mixture, and combining the fluorine-based constituent and water into the least one solvent or solvent mixture to form the wet etching chemistry solution.

This application is a PCT application which claims priority to U.S. patent application Ser. No. 10/938,191 filed on Sep. 10, 2004, which is commonly-owned and incorporated herein in its entirety by reference.

### FIELD OF THE INVENTION

This invention relates generally to semiconductor manufacturing and, in particular, to an etchant capable of etching high k (dielectric constant) dielectric materials.

### BACKGROUND OF THE INVENTION

As transistor dimensions continue to shrink, the channel length (the distance between the source and the drain) will shrink as well. A shorter channel means faster transition switching because the charger carriers have a shorter distance to travel. However, it becomes harder for the gate to maintain control over the channel. Instead, the voltage on the drain begins to lower the energy barrier in the channel, reducing the threshold voltage and freeing carriers to flow even when there is no voltage on the gate. This is referred to as the short-channel effect and causes power consumption to rise and ultimately destroys transistor-switching action completely.

Ideally, the gate controls or holds electrons in the channels strictly through capacitive coupling, being separated from the channel by an oxide insulating barrier immune to the passage of charge carriers. However, for the 90 nanometer node and below, the thickness of the gate oxide is shrinking to less than 2 nanometers. An oxide this thin allows a significant amount of current to flow from gate to channel substrate.

One solution to this problem is the replacement of the gate insulation, silicon dioxide, with the material having a higher dielectric constant. Thus, a gate over a thick, high-k insulator can control the channel just as effectively as one over a thinner lower-k insulator. Several promising candidates are being studied, including hafnium dioxide, hafnium silicate, HfSiON, zirconium oxide and zirconium silicate. Hafnium dioxide, whose dielectric constant (k) is about 22 for example, allows the gate to control the channel despite the oxide being several times thicker than silicon dioxide.

During the semiconductor manufacturing process, once the transistor gate is formed the exposed stack must be removed from the source and drain regions of the transistor. Thus, when using high dielectric constant materials, such as those mentioned herein, as the gate oxide, the high dielectric constant material must be selectively removed. As dry etching techniques rely on the formation of volatile compounds, there are no viable dry etching techniques suitable for the removal of these high dielectric constant materials, as no volatile hafnium (Hf) or zirconium (Zr) compounds exist. Therefore, these high dielectric constant materials will have to be removed through wet etching. Current etchants for wet etching, e.g., hydrofluoric acid (HF) solutions, do not possess the requisite etch selectivity between the high dielectric constant materials and thermally grown silicon dioxide and silicon dioxide formed by the decomposition of tetraethylorthosilicate (TEOS), which may be present on the semiconductor substrate.

Therefore, there are several goals that should be addressed when formulating etchants to remove high dielectric constant materials, such as those disclosed herein. Important considerations are a) selective wet etchant that will remove high dielectric constant materials while not removing other layers, such as thermal oxides or TEOS; b) etchants that are not significantly flammable, as compared to etchants containing alcohols; c) etchants that can selectively and efficiently etch at or near room temperature; d) etchants that can etch surfaces that are sputtered/roughened prior to etching or not sputtered/roughened at all and e) etchants that are cost efficient to produce/manufacture.

### SUMMARY OF THE INVENTION

An etchant for selective removal of high dielectric constant materials is described herein that comprises at least one fluorine-based constituent; water and at least one solvent or solvent mixture.

Methods are also described herein for producing a wet etching chemistry solution that include providing at least one fluorine-based constituent, providing water; providing at least one solvent or solvent mixture, and combining the fluorine-based constituent and water into the at least one solvent or solvent mixture to form the wet etching chemistry solution.

### BRIEF DESCRIPTION OF THE DRAWINGS

FIGS. 1A and 1B illustrate the effect on the hafnium dioxide etch rate when the hydrochloric acid weight percent decreases in accordance with one embodiment of the invention.

FIGS. 2A and 2B illustrate the effect on the hafnium dioxide/thermal oxide etch selectivity with changes in BF concentration in accordance with one embodiment of the invention.

FIGS. 3A and 3B illustrate the effect on the hafnium dioxide/TEOS etch selectivity with changes in the HCl and H₂O concentration in accordance with one embodiment of the invention.

FIGS. 4A and 4B show surface (4A) and contour (4B) plots of the HfO₂ etch rate as a function of the concentrations of component A and component B.

FIGS. 5A and 5B show surface (5A) and contour (5B) plots of the HfSiO etch rate as a function of the concentrations of component A and component B.

FIGS. 6A and 6B show surface (6A) and contour (6B) plots of the thermal oxide (TOx) etch rate as a function of the concentrations of component A and component B.

FIGS. 7A and 7B show surface (7A) and contour (7B) plots of the TEOS etch rate as a function of the concentrations of component A and component B.

FIGS. 8A and 8B show surface (8A) and contour (8B) plots of the HfO₂/TOx etch selectivity as a function of the concentrations of component A and component B.

FIGS. 9A and 9B show surface (9A) and contour (9B) plots of the HfO₂/TEOS etch selectivity as a function of the concentrations of component A and component B.

FIGS. 10A and 10B show surface (10A) and contour (10B) plots of the HfSiO/TOx etch selectivity as a function of the concentrations of component A and component B.

FIGS. 11A and 11B show surface (11A) and contour (11B) plots of the HfSiO/TEOS etch selectivity as a function of the concentrations of component A and component B.

### DETAILED DESCRIPTION

As described herein, etchants have been developed that a) selectively remove high dielectric constant materials while not removing other layers, such as thermal oxides or TEOS; b) are not significantly flammable, as compared to etchants containing alcohols; c) can selectively and efficiently etch at or near room temperature; d) etch surfaces that are sputtered/roughened prior to etching or not sputtered/roughened at all and e) are cost efficient to produce/manufacture.

An etchant for selective removal of high dielectric constant materials is described herein that comprises at least one fluorine-based constituent; water and at least one solvent or solvent mixture. In additional embodiments, other constituents may be added to the basic wet etchant, including hydrochloric acid. In some embodiments, an etchant for selective removal of high dielectric constant materials can be formed comprising at least one fluorine-based constituent; water and at least one solvent or solvent mixture, whereby the solution does not contain hydrochloric acid or alcohol. In other embodiments, an etchant for selective removal of high dielectric constant materials can be formed comprising at least one fluorine-based constituent; water and at least one solvent or solvent mixture, whereby the solution does not contain a component designed, intended or developed for removing water from the solution.

Wet etchants described herein can selectively remove high dielectric constant materials, such as hafnium dioxide, hafnium silicate, HfSiON, zirconium oxide and zirconium silicate, while not removing other components, such as silicon, tetraethylorthosilicate (TEOS), and thermal oxide. In addition, contemplated wet etchants are highly selective to Si₃N₄, silicides, and/or metals such as tungsten, in that those components are not etched or removed by wet etchants described herein.

Methods of forming and uses of these wet etching chemistries are also contemplated and described herein. Such methods include providing the constituents of the wet etching chemistry formulation, blending the constituents to form the formulation and applying the formulation to a surface or substrate. In some embodiments, the formulation may be produced in situ (directly on the surface) or may be formed before application to the surface. Specifically, methods are described herein for producing a wet etching chemistry solution that include providing at least one fluorine-based constituent, providing water; providing at least one solvent or solvent mixture, and combining the fluorine-based constituent and water into the at least one solvent or solvent mixture to form the wet etching chemistry solution. In additional embodiments, other constituents may be added to the basic wet etchant using methods described herein, including hydrochloric acid. In some embodiments, a method for producing an etchant for selective removal of high dielectric constant materials can be formed comprising providing at least one fluorine-based constituent; providing water and providing at least one solvent or solvent mixture; and combining those constituents, whereby the solution does not contain hydrochloric acid or alcohol.

The wet etching chemistry solutions are in aqueous environments. As used herein, the term “environment” means that environment in the solution containing the at least one fluorine-based constituent, water and the at least one solvent or solvent mixture. The term “environment” does not mean the environment surrounding the solution, such as the environment present in the lab or in the building.

The at least one fluorine-based constituent may be present in solution in an amount less than about 70% by weight. In some embodiments, the at least one fluorine-based constituent is present in solution in an amount from about 0.005% to about 70% by weight. In other embodiments, the at least one fluorine-based constituent is present in solution in an amount from about 0.005% to about 45% by weight. In yet other embodiments, the at least one fluorine-based constituent is present in solution in an amount from about 0.005% to about 20% by weight. And in some embodiments, the at least one fluorine-based constituent is present in solution in an amount from about 0.005% to about 5% by weight. In other embodiments, the at least one fluorine-based constituent is present in solution in an amount from about 0.1% to about 10%. In yet other embodiments, the at least one fluorine-based constituent is present in solution in an amount from about 0.5% to about 0.85%.

The wet etchants described herein also comprise water. In some embodiments, the wet etchants comprise between about 0 and 10 weight percent of water. In other embodiments, the wet etchants comprise between about 0 and 5 weight percent of water. In yet other embodiments, the wet etchants comprise between about 0.1 and about 5 weight percent of water.

As mentioned, the wet etchants disclosed herein comprise at least one fluorine-based constituent. The at least one fluorine-based constituent may comprise any suitable fluoride source, such as hydrogen fluoride, ammonium fluoride, tetramethylammonium fluoride, tetrabutylammonium fluoride, tetraethylammonium fluoride, benzyltrimethylammonium fluoride, pyridine hydrogen fluoride, ammonium bifluoride or combinations thereof. In some embodiments, the at least one fluorine-based constituent comprises hydrogen fluoride. The hydrogen fluoride may be aqueous or non-aqueous. If the hydrogen fluoride or fluoride-based constituent comprises water, that weight percent of water is considered at least part of the water component of the etchant described herein. Water may also be added to the solution as a separate constituent apart from any water found in the at least one fluorine-based constituent or the solvent and/or solvent mixture.

The at least one fluorine-based constituent is added to at least one solvent or solvent mixture. Contemplated solvents include any suitable pure or mixture of organic molecules that are volatilized at a desired temperature, such as the critical temperature, or that can facilitate any of the above-mentioned design goals or needs. The solvent may also comprise any suitable pure or mixture of polar and non-polar compounds. As used herein, the term “pure” means that component that has a constant composition. For example, pure water is composed solely of H₂O. As used herein, the term “mixture” means that component that is not pure, including salt water. As used herein, the term “polar” means that characteristic of a molecule or compound that creates an unequal charge, partial charge or spontaneous charge distribution at one point of or along the molecule or compound. As used herein, the term “non-polar” means that characteristic of a molecule or compound that creates an equal charge, partial charge or spontaneous charge distribution at one point of or along the molecule or compound. One of ordinary skill in the art of chemistry and etching solutions will know which solvents are non-polar and which solvents are clearly polar in nature.

The solvent or solvent mixture (comprising at least two solvents) comprises those solvents that are considered part of the hydrocarbon family of solvents. Hydrocarbon solvents are those solvents that comprise carbon and hydrogen. It should be understood that a majority of hydrocarbon solvents are non-polar; however, there are a few hydrocarbon solvents that could be considered polar. Hydrocarbon solvents are generally broken down into three classes: aliphatic, cyclic and aromatic. Aliphatic hydrocarbon solvents may comprise both straight-chain compounds and compounds that are branched and possibly crosslinked, however, aliphatic hydrocarbon solvents are not considered cyclic. Cyclic hydrocarbon solvents are those solvents that comprise at least three carbon atoms oriented in a ring structure with properties similar to aliphatic hydrocarbon solvents. Aromatic hydrocarbon solvents are those solvents that comprise generally three or more unsaturated bonds with a single ring or multiple rings attached by a common bond and/or multiple rings fused together. Contemplated hydrocarbon solvents include toluene, xylene, p-xylene, m-xylene, mesitylene, solvent naphtha H, solvent naphtha A, alkanes, such as pentane, hexane, isohexane, heptane, nonane, octane, dodecane, 2-methylbutane, hexadecane, tridecane, pentadecane, cyclopentane, 2,2,4-trimethylpentane, petroleum ethers, halogenated hydrocarbons, such as chlorinated hydrocarbons, nitrated hydrocarbons, benzene, 1,2-dimethylbenzene, 1,2,4-trimethylbenzene, mineral spirits, kerosine, isobutylbenzene, methylnaphthalene, ethyltoluene, ligroine. Particularly contemplated solvents include, but are not limited to, pentane, hexane, heptane, cyclohexane, benzene, toluene, xylene and mixtures or combinations thereof.

The solvent or solvent mixture may comprise those solvents that are not considered part of the hydrocarbon solvent family of compounds, such as ketones, such as acetone, diethyl ketone, methyl ethyl ketone and the like, alcohols, esters, ethers and amines. Other contemplated solvents include propylene carbonate, butylene carbonate, ethylene carbonate, gamma-butyrolactone, propylene glycol, ethyl lactate, propylene glycol monomethyl ether acetate or a combination thereof. In yet other contemplated embodiments, the solvent or solvent mixture may comprise a combination of any of the solvents mentioned herein.

The at least one solvent or solvent mixture may those solvents that contain nitrogen atoms, phosphorus atoms, sulfur atoms or a combination thereof, such as N-methyl-2-pyrrolidone, N,N-dimethylacetamide, dimethyl sulfoxide, pyridine or a combination thereof. Both the etching and the cleaning solutions contemplated herein also utilize a compatible solvent constituent.

Solvents and solvent mixtures may be present in solution in an amount less than about 99.5% by weight. In some embodiments, the solvents or solvent mixtures may be present in solution in an amount from about 30% to about 99.5% by weight.

The solvents used herein may comprise any suitable impurity level, such as less than about 1 ppm, less than about 100 ppb, less than about 10 ppb, less than about 1 ppb, less than about 100 ppt, less than about 10 ppt and in some cases, less than about 1 ppt. These solvents may be purchased having impurity levels that are appropriate for use in these contemplated applications or may need to be further purified to remove additional impurities and to reach the less than about 10 ppb, less than about 1 ppb, less than about 100 ppt or lower levels that are becoming more desirable in the art of etching and cleaning.

The at least one fluorine-based constituent, the at least one solvent or solvent mixture and/or any other constituent/additive mentioned herein may be provided by any suitable method, including a) buying at least some of at least one fluorine-based constituent, the at least one solvent or solvent mixture and/or any other constituent/additive mentioned herein from a supplier; b) preparing or producing at least some of the at least one fluorine-based constituent, the at least one solvent or solvent mixture and/or any other constituent/additive mentioned herein in house using chemicals provided by another source and/or c) preparing or producing at least some of the at least one fluorine-based constituent, the at least one solvent or solvent mixture and/or any other constituent/additive mentioned herein in house using chemicals also produced or provided in house or at the location.

In one embodiment, the etchant is a solution of hydrofluoric acid and water at relatively low concentrations, i.e., less than 2% weight percent for each component. The remainder of the solution is a non-polar solvent or a solvent that is less polar than water. In another embodiment, the etchant is a solution of hydrofluoric acid, hydrochloric acid and water at relatively low concentrations, i.e., less than 2% weight percent for each component. The remainder of the solution is a non-polar solvent or a solvent that is less polar than water.

It should be appreciated that the etchant composition described above may also be used in a method for etching a semiconductor substrate having a high k dielectric, such as those described herein. One contemplated method of etching a high dielectric constant material comprises a) providing an etching solution such as those described herein; b) providing a layered material comprising a high dielectric constant material; c) applying the etching solution to the layered material; and d) etching at least part of the high dielectric constant material. Another contemplated method includes a two step etch process where the first step is a dry etch and the second step is a wet etch using the etchant described herein. The first step includes sputter etching with a plasma having a heavy positive ion, e.g., an Argon based plasma. Here, approximately 50% of the high dielectric constant material film is removed. In one embodiment, the high dielectric constant material film is approximately 100 Å thick, therefore, approximately 50 Å of this layer is removed through the sputter etch step. It should be appreciated that the sputter etch process may be performed through any suitable sputter etch chamber. Most of the remaining 50 Å of the high dielectric constant material layer will be damaged by the sputter etch process, thereby making it easier for the second step, i.e., the wet etch process, to remove the remaining hafnium dioxide layer.

Following the sputter etch process, the wet etchant solution described above is applied to the semiconductor substrate to remove the remaining portion of the high dielectric constant material layer. Thus, the plasma etch initiates the two step process and provides for an anisotropic etch which damages the remaining layer of high dielectric constant material. Thereafter, the wet etchant is applied and the enhanced etch selectivity enabled through the non-polar solvent (as mentioned above, a solvent less polar than water may alternatively be used) removes the remaining portion of the high dielectric constant material layer without causing notches, i.e., providing a desirable sidewall profile. In addition, the enhanced etch selectivity prevents etching through the silicon dioxide/thermal oxide.

A wet etchant and a method of using the wet etchant for a semiconductor fabrication process using a high dielectric constant material is described herein. By preventing the dissociation of HF through the use of a non-polar solvent, or a solvent less polar than water, the wet etchant becomes highly selective to silicon, TEOS, thermal oxide, Si₃N₄, silicides, and metals, such as, for example, tungsten. In one embodiment the etch rate is between about 5 to 25 angstroms per minute. In another embodiment the wet etchant described herein is metal free. Furthermore, because the wet etchant composition described above is nonvolatile, the composition is relatively safe as compared to other available wet etchants.

Wafers and layered materials contemplated herein comprise those wafers and layered materials that are utilized or considered to be utilized in semiconductor or electronic applications, such as dual damascene structures, and comprise at least one layer of material. Surfaces contemplated herein may comprise any desirable substantially solid material, such as a substrate, wafer or other suitable surface. Particularly desirable substrate layers would comprise films, organic polymer, inorganic polymer, glass, ceramic, plastic, metal or coated metal, or composite material. Surface and/or substrate layers comprise at least one layer and in some instances comprise a plurality of layers. In other embodiments, the substrate comprises a material common in the integrated circuit industries as well as the packaging and circuit board industries such as silicon, copper, glass, and another polymer. Suitable surfaces contemplated herein may also include another previously formed layered stack, other layered component, or other component altogether. An example of this may be where a dielectric material and CVD barrier layer are first laid down as a layered stack—which is considered the “surface” for the subsequently spun-on layered component.

At least one layer may be coupled to the surface or substrate creating a multilayered stack. As used herein, the term “coupled” means that the surface and layer or two layers are physically attached to one another or there's a physical attraction between two parts of matter or components, including bond forces such as covalent and ionic bonding, and non-bond forces such as Van der Waals, electrostatic, coulombic, hydrogen bonding and/or magnetic attraction. Also, as used herein, the term coupled is meant to encompass a situation where the surface and layer or two layers are directly attached to one another, but the term is also meant to encompass the situation where the surface and the layer or plurality of layers are coupled to one another indirectly—such as the case where there's an adhesion promoter layer between the surface and layer or where there's another layer altogether between the surface and layer or plurality of layers.

Contemplated dielectric and low dielectric materials that may be used on wafers and layered materials comprise inorganic-based compounds, such as silicon-based disclosed in commonly assigned U.S. Pat. No. 6,143,855 and pending U.S. Ser. No. 10/078,919 filed Feb. 19, 2002; (for example Honeywell NANOGLASS® and HOSP® products), gallium-based, germanium-based, arsenic-based, boron-based compounds or combinations thereof, and organic-based compounds, such as polyethers, polyarylene ethers disclosed in commonly assigned U.S. Pat. No. 6,124,421 (such as Honeywell FLARE™ product), polyimides, polyesters and adamantane-based or cage-based compounds disclosed in commonly assigned WO 01/78110 and WO 01/08308 (such as Honeywell GX-3™ product). The dielectric and low dielectric materials may be applied by spin coating the material on to the surface, dip coating, spray coating, rolling the material on to the surface, dripping the material on to the surface, and/or spreading the material on to the surface.

Examples of silicon-based compounds comprise siloxane compounds, such as methylsiloxane, methylsilsesquioxane, phenylsiloxane, phenylsilsesquioxane, methylphenylsiloxane, methylphenylsilsesquioxane, silazane polymers, silicate polymers and mixtures thereof. A contemplated silazane polymer is perhydrosilazane, which has a “transparent” polymer backbone where chromophores can be attached. Examples of siloxane polymers and blockpolymers include hydrogensiloxane polymers of the general formula (H_{0-1.0}SiO_{1.5-2.0})ₓ and hydrogensilsesquioxane polymers, which have the formula (HSiO_{1.5})ₓ, where x is greater than about four. Also included are copolymers of hydrogensilsesquioxane and an alkoxyhydridosiloxane or hydroxyhydridosiloxane. Spin-on glass materials additionally include organohydridosiloxane polymers of the general formula (H_{0-1.0}SiO_{1.5-2.0})ₙ(R_{0-1.0}SiO_{1.5-2.0})ₘ, and organohydridosilsesquioxane polymers of the general formula (HSiO_{1.5})ₙ(RSiO_{1.5})ₘ, where m is greater than zero and the sum of n and m is greater than about four and R is alkyl or aryl. Some useful organohydridosiloxane polymers have the sum of n and m from about four to about 5000 where R is a C₁-C₂₀ alkyl group or a C₆-C₁₂ aryl group. The organohydridosiloxane and organohydridosilsesquioxane polymers are alternatively denoted spin-on-polymers. Some specific examples include alkylhydridosiloxanes, such as methylhydridosiloxanes, ethylhydridosiloxanes, propylhydridosiloxanes, t-butylhydridosiloxanes, phenylhydridosiloxanes; and alkylhydridosilsesquioxanes, such as methylhydridosilsesquioxanes, ethylhydridosilsesquioxanes, propylhydridosilsesquioxanes, t-butylhydridosilsequioxanes, phenylhydridosilsesquioxanes, and combinations thereof. Several of the contemplated spin-on materials are described in the following issued patents and pending applications, which are herein incorporated by reference in their entirety: (PCT/US00/15772 filed Jun. 8, 2000; U.S. application Ser. No. 09/330,248 filed Jun. 10, 1999; U.S. application Ser. No. 09/491,166 filed Jun. 10, 1999; U.S. Pat. No. 6,365,765 issued on Apr. 2, 2002; U.S. Pat. No. 6,268,457 issued on Jul. 31, 2001; U.S. application Ser. No. 10/001,143 filed Nov. 10, 2001; U.S. application Ser. No. 09/491,166 filed Jan. 26, 2000; PCT/US00/00523 filed Jan. 7, 1999; U.S. Pat. No. 6,177,199 issued Jan. 23, 2001; U.S. Pat. No. 6,358,559 issued Mar. 19, 2002; U.S. Pat. No. 6,218,020 issued Apr. 17, 2001; U.S. Pat. No. 6,361,820 issued Mar. 26, 2002; U.S. Pat. No. 6,218,497 issued Apr. 17, 2001; U.S. Pat. No. 6,359,099 issued Mar. 19, 2002; U.S. Pat. No. 6,143,855 issued Nov. 7, 2000; and U.S. application Ser. No. 09/611,528 filed Mar. 20, 1998).

Solutions of organohydridosiloxane and organosiloxane resins can be utilized for forming caged siloxane polymer films that are useful in the fabrication of a variety of electronic devices, micro-electronic devices, particularly semiconductor integrated circuits and various layered materials for electronic and semiconductor components, including hardmask layers, dielectric layers, etch stop layers and buried etch stop layers. These organohydridosiloxane resin layers are quite compatible with other materials that might be used for layered materials and devices, such as adamantane-based compounds, diamantane-based compounds, silicon-core compounds, organic dielectrics, and nanoporous dielectrics. Compounds that are considerably compatible with the organohydridosiloxane resin layers contemplated herein are disclosed in PCT Application PCT/US01/32569 filed Oct. 17, 2001; PCT Application PCT/US01/50812 filed Dec. 31, 2001; U.S. application Ser. No. 09/538,276; U.S. application Ser. No. 09/544,504; U.S. application Ser. No. 09/587,851; U.S. Pat. No. 6,214,746; U.S. Pat. No. 6,171,687; U.S. Pat. No. 6,172,128; U.S. Pat. No. 6,156,812, U.S. Application Ser. No. 60/350,187 filed Jan. 15, 2002; and U.S. 60/347,195 filed Jan. 8, 2002, which are all incorporated herein by reference in their entirety.

Nanoporous silica dielectric films with dielectric constants ranging from about 1.5 to about 4 can be also as at least one of the layers. Nanoporous silica compounds contemplated herein are those compounds found in U.S. Pat. Nos. 6,022,812; 6,037,275; 6,042,994; 6,048,804; 6,090,448; 6,126,733; 6,140,254; 6,204,202; 6,208,041; 6,318,124 and 6,319,855. These types of films are laid down as a silicon-based precursor, aged or condensed in the presence of water and heated sufficiently to remove substantially all of the porogen and to form voids in the film. The silicon-based precursor composition comprises monomers or prepolymers that have the formula: Rₓ—Si-L_{y}, wherein R is independently selected from alkyl groups, aryl groups, hydrogen and combinations thereof, L is an electronegative moiety, such as alkoxy, carboxy, amino, amido, halide, isocyanato and combinations thereof, x is an integer ranging from 0 to about 2, and y is an integer ranging from about 2 to about 4. Other nanoporous compounds and methods can be found in U.S. Pat. Nos. 6,156,812; 6,171,687; 6,172,128; 6,214,746; 6,313,185; 6,380,347; and 6,380,270, which are incorporated herein in their entirety.

Cage molecules or compounds, as described in detail herein, can also be groups that are attached to a polymer backbone, and therefore, can form nanoporous materials where the cage compound forms one type of void (intramolecular) and where the crosslinking of at least one part of the backbone with itself or another backbone can form another type of void (intermolecular). Additional cage molecules, cage compounds and variations of these molecules and compounds are described in detail in PCT/US01/32569 filed on Oct. 18, 2001, which is herein incorporated by reference in its entirety.

Contemplated anti-reflective and absorbing coating materials for ultraviolet photolithography may comprise at least one inorganic-based compound or inorganic material, at least one absorbing compound and in some cases, at least one material modification agent, such as those disclosed in PCT Applications PCT/US02/36327 filed on Nov. 12, 2002; PCT/US03/36354 filed on Nov. 12, 2003 and in U.S. application Ser. No. 10/717,028 filed on Nov. 18, 2003. The at least one material modification agent may include any compound or composition that can modify the coating material to improve the photolithographic, compatibility and/or physical quality of the resulting film, such as by improving the etch selectivity and/or stripping selectivity or by minimizing the fill bias. The at least one material modification agent may comprise at least one porogen, at least one leveling agent, at least one high-boiling solvent, at least one densifying agent, at least one catalyst, at least one pH tuning agent, at least one capping agent, at least one replacement solvent, at least one adhesion promoter, such as a resin-based material and/or a combination thereof that are incorporated into the inorganic-based material or compound.

The sacrificial compositions and materials may be laid down or formed as a continuous layer of material, in a pattern, in a non-continuous form or as a combination thereof. As used herein, the phrase “non-continuous form” means that the composition or material is not laid down in a continuous layer and is also not laid down in a pattern. The composition or material in a non-continuous form is laid down or formed having a more random or non-pattern-like appearance.

Other contemplated layers may include solder materials, coating compositions and other related materials, including solder pastes, polymer solders and other solder-based formulations and materials, such as those found in the following Honeywell International Inc.'s issued patents and pending patent applications, which are incorporated herein in their entirety: U.S. patent application Ser. Nos. 09/851,103, 60/357,754, 60/372,525, 60/396,294, and 09/543,628; and PCT Pending Application Serial No.: PCT/US02/14613, and all related continuations, divisionals, continuation-in-parts and foreign applications.

Electronic-based products can be “finished” in the sense that they are ready to be used in industry or by other consumers. Examples of finished consumer products are a television, a computer, a cell phone, a pager, a palm-type organizer, a portable radio, a car stereo, and a remote control. Also contemplated are “intermediate” products such as circuit boards, chip packaging, and keyboards that are potentially utilized in finished products.

Electronic products may also comprise a prototype component, at any stage of development from conceptual model to final scale-up/mock-up. A prototype may or may not contain all of the actual components intended in a finished product, and a prototype may have some components that are constructed out of composite material in order to negate their initial effects on other components while being initially tested.

As used herein, the term “electronic component” means any device or part that can be used in a circuit to obtain some desired electrical action. Electronic components contemplated herein may be classified in many different ways, including classification into active components and passive components. Active components are electronic components capable of some dynamic function, such as amplification, oscillation, or signal control, which usually requires a power source for its operation. Examples are bipolar transistors, field-effect transistors, and integrated circuits. Passive components are electronic components that are static in operation, i.e., are ordinarily incapable of amplification or oscillation, and usually require no power for their characteristic operation. Examples are conventional resistors, capacitors, inductors, diodes, rectifiers and fuses.

Electronic components contemplated herein may also be classified as conductors, semiconductors, or insulators. Here, conductors are components that allow charge carriers (such as electrons) to move with ease among atoms as in an electric current. Examples of conductor components are circuit traces and vias comprising metals. Insulators are components where the function is substantially related to the ability of a material to be extremely resistant to conduction of current, such as a material employed to electrically separate other components, while semiconductors are components having a function that is substantially related to the ability of a material to conduct current with a natural resistivity between conductors and insulators. Examples of semiconductor components are transistors, diodes, some lasers, rectifiers, thyristors and photosensors.

Electronic components contemplated herein may also be classified as power sources or power consumers. Power source components are typically used to power other components, and include batteries, capacitors, coils, and fuel cells. As used herein, the term “battery” means a device that produces usable amounts of electrical power through chemical reactions. Similarly, rechargeable or secondary batteries are devices that store usable amounts of electrical energy through chemical reactions. Power consuming components include resistors, transistors, ICs, sensors, and the like.

Still further, electronic components contemplated herein may also be classified as discreet or integrated. Discreet components are devices that offer one particular electrical property concentrated at one place in a circuit. Examples are resistors, capacitors, diodes, and transistors. Integrated components are combinations of components that that can provide multiple electrical properties at one place in a circuit. Examples are ICs, i.e., integrated circuits in which multiple components and connecting traces are combined to perform multiple or complex functions such as logic.

### EXAMPLES

### Example 1

In one embodiment, the etch selectivity of the etchant, with respect to the above-mentioned components, may be modified by adjusting the weight percent of water in the solution. Exemplary ranges of the components of the etchant solution are provided in Table 1.

TABLE 1

| Factor | High | Middle | Low |
|---|---|---|---|
| HF conc. (w/0) | 0.85 | 0.71 | 0.57 |
| HCl conc. (w/0) | 0.23 | 0.19 | 0.15 |
| H₂O conc. (w/0) | 1.27 | 1.06 | 0.85 |

Table 1 illustrates concentrations in weight percent for the components of several embodiments of the wet etchant in accordance with one embodiment of the invention. The hydrofluoric acid (HF) concentration is shown ranging from a low weight percent of 0.57 to a high weight percent of 0.85. The hydrochloric acid (HCl) concentration ranges from 0.15 weight percent to 0.23 weight percent. The water (H₂O) concentration ranges from 0.85 weight percent to 1.27 weight percent. It should be appreciated that the ranges listed in Table 1 are exemplary and not meant to be limiting. For example, the range for HF may be extended to about 0.1% to about 10%. Likewise the range for the HCl and the H₂O may be extended to about 0% to about 2%, and about 0% to about 5%, respectively. It should be understood that contemplated etching solutions and chemistries described herein can be effective without hydrochloric acid.

Propylene carbonate is a preferred solvent less polar than water, as the propylene carbonate is less volatile, e.g., has a higher flashpoint, than lightweight alcohols and less polar than lightweight alcohols. As a result of the higher flashpoint, the process temperature may be at room temperature, i.e., approximately 20 Celsius (C), or above. In one embodiment, the process temperature for the wet etchant application is between about −10 C and about 50 C. It should be appreciated that the non-polar solvent, slightly polar solvent or solvent less polar than water, enables more of the HF to remain in a non-dissociated form. In contrast, an aqueous solution of dilute HF results in most of the HF to dissociate into H⁺ and F⁺ ions. In the presence of a strong acid, bifluoride ions (HF₂⁻) also form. Dilute HF chemistries in water will etch these high dielectric constant materials, but have no etch selectivity to silicon dioxide. However, by decreasing or minimizing the HF₂⁻ concentration in the etchant, the silicon dioxide etch rate may be suppressed, thereby providing the etch selectivity required for the use of a wet etchant to be applied to remove the high dielectric constant material.

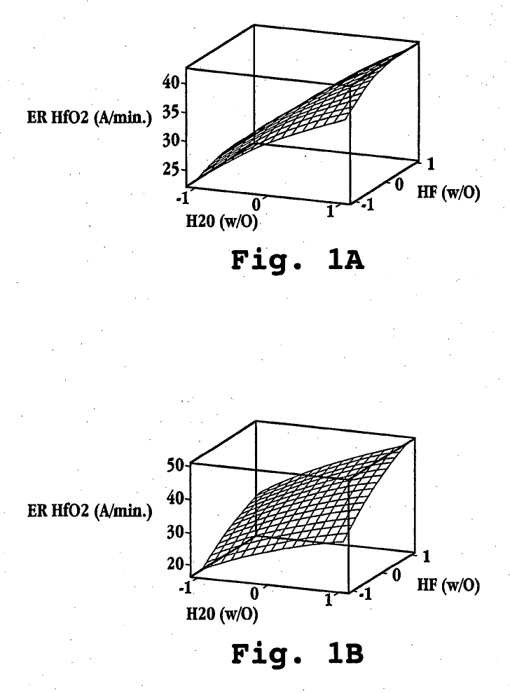

FIGS. 1A and 1B illustrate the effect on the etch rate of a contemplated high dielectric constant material—hafnium dioxide—when the hydrochloric acid weight percent decreases in accordance with one embodiment of the invention. In FIG. 1A the HCl concentration is held at the high held factor, i.e., 0.23 weight percent. In FIG. 1B the HCl concentration is held at the low held factor, i.e., 0.15 weight percent. As shown by comparing FIGS. 1A and 1B, the hafnium dioxide etch rate increases as the HCl concentration decreases. It should be appreciated that the −1, 0, and 1 locations on the axes of FIGS. 1A-3B represent the low, middle, and high factors of Table 1 for the corresponding component. Thus, with reference to FIG. 1A, the −1 location for the H₂O weight percent corresponds to the 0.85 weight percent of Table 1, the 0 location for the H₂O weight percent corresponds to the 1.06 weight percent of Table 1, and so on. The etch rates of FIGS. 1A and 1B were measured using a reflectometer when using unpatterned wafers and a profilometer when using patterned wafers.

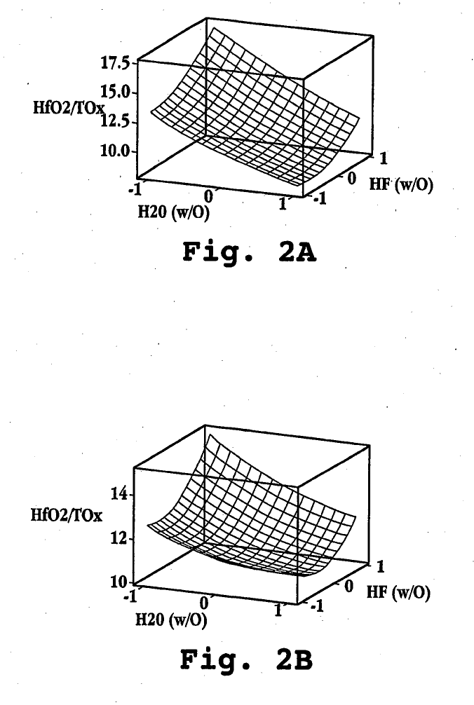

FIGS. 2A and 2B illustrate the effect on the hafnium dioxide/thermal oxide etch selectivity with changes in HF concentration in accordance with one embodiment of the invention. In FIG. 2A the HF concentration is held at the high held factor, i.e., 0.85 weight percent. In FIG. 2B the HF concentration is held at the low held factor, i.e., 0.57 weight percent. As shown by comparing FIGS. 2A and 2B, the hafnium dioxide/thermal oxide etch selectivity increases as the HF concentration increases.

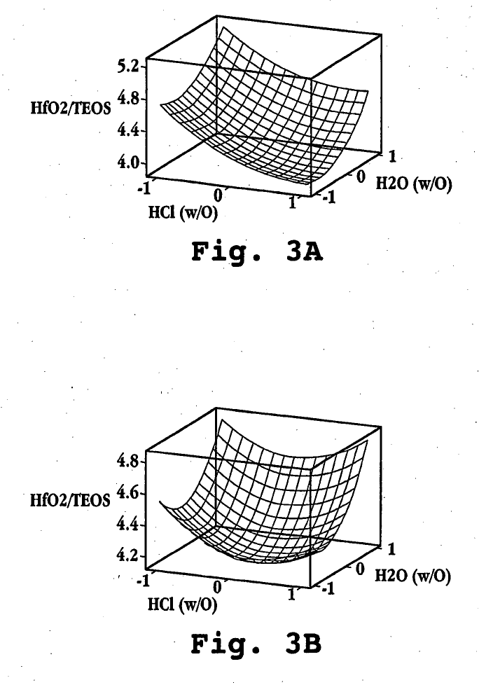

FIGS. 3A and 3B illustrate the effect on the hafnium dioxide/TEOS etch selectivity with changes in the HCl and the H₂O concentration in accordance with one embodiment of the invention. In FIG. 3A the HF concentration is held at the high held factor, i.e., 0.85 weight percent. In FIG. 2B the HF concentration is held at the mid held factor, i.e., 0.71 weight percent. As shown by comparing FIGS. 3A and 3B, the hafnium dioxide/TEOS etch selectivity increases as the HF concentration increases. Furthermore, within FIGS. 3A and 3B, the hafnium dioxide/TEOS etch selectivity increases with increasing water concentration and decreasing HCl Concentration.

### Example 2

A central composite response surface design was utilized in this study [R. H. Myers and D. C. Montgomery, Response Surface Methodology, 2^{nd} ed. John Wiley & Sons, New York, (2002)]. The etchant composition consisted of two components (A and B) dissolved in a solvent. Each factor was studied at a high (+1), middle (0) and low (−1) setting. A two-factor, three-level central composite design with five center points consists of 13 runs (experiments). The factor setting for each run is summarized in Table 2. Column one contains the run order of the 13 experiments. Columns two and three contain the concentration factor settings of component A and component 13 respectively for each run.

TABLE 2
Run Order and Factor Settings

Factor Settings

| Run | Component A | Component B |
|---|---|---|
| Order | Concentration | Concentration |
| 1 | 0 | +1 |
| 2 | +1 | 0 |
| 3 | 0 | 0 |
| 4 | 0 | −1 |
| 5 | 0 | 0 |
| 6 | −1 | 0 |
| 7 | +1 | −1 |
| 8 | −1 | +1 |
| 9 | 0 | 0 |
| 10 | +1 | +1 |
| 11 | 0 | 0 |
| 12 | −1 | −1 |
| 13 | 0 | 0 |

Each of the 13 DOE runs involved the timed immersion of four wafer coupons in a solution with the appropriate concentration of the two components as depicted in Table 2. Film thickness loss of HfO₂, HfSiO, TOx, and TEOS was determined as a function of time. Film thickness loss was determined by measuring the film thickness prior to and following immersion in the etchant. The film thickness of the TOx and TEOS films was measured employing a Nanometrics NanoSpec AFT 4000 reflectometer. A Gaertner Scientific Corporation L116A ellipsometer was utilized to measure the HfO₂ and HfSiO film thickness. All etchant solutions were held at a constant temperature of 20° C. A stopwatch was utilized to measure the time that each coupon was immersed in the etchant (i.e. the etch time).

The HfO₂ film utilized in this study was deposited onto a silicon substrate using atomic layer deposition (ALD) techniques. After deposition, the HfO₂-coated wafer was annealed in an N₂ atmosphere at 1100° C. After annealing, the surface of the HfO₂ film was damaged by sputtering the surface with argon ions.

The HfSiO film was deposited onto a silicon substrate by sputtering a 90 weight percent HfO2-10 weight percent SiO₂ target. After sputter-deposition, the HfSiO-coated wafer was annealed in an N₂ atmosphere at 1100° C. After annealing, the surface of the HfSiO film was damaged by sputtering that surface with argon ions.

A summary of the metrology tools used and the etch rates and etch selectivities obtained are presented in Table 3. The coupon types used, measured film thickness loss, metrology tool utilized, calculated etch rates, and calculated etch selectivities are contained in columns one through five respectively.

TABLE 3
Experimental Summary

| | Film | | | |
|---|---|---|---|---|
| | Thickness | Metrology | Etch | Etch |
| Coupon Type | Loss | Tool | Rate | Selectivity |
| Sputter-damaged, | HfO₂ | Ellipsometer | HfO₂ | HfO₂/TOx |
| Annealed in N2 at | | | | |
| 1100° C., | | | | |
| ALD HfO₂ Film on | | | | |
| Silicon | | | | |
| Sputter-damaged, | HfSiO | Ellipsometer | HfSiO | HfO₂/TEOS |
| Annealed in N2 at | | | | |
| 1100° C., | | | | |
| MOCVD HfSiO | | | | |
| Film on Silicon | | | | |
| Thermally Grown | TOx | Reflectometer | TOx | HfSiO/TOx |
| SiO₂ (TOx) | | | | |
| on Silicon | | | | |
| TEOS Based SiO₂ | TEOS | Reflectometer | TEOS | HfSiO/TEOS |
| on Silicon | | | | |

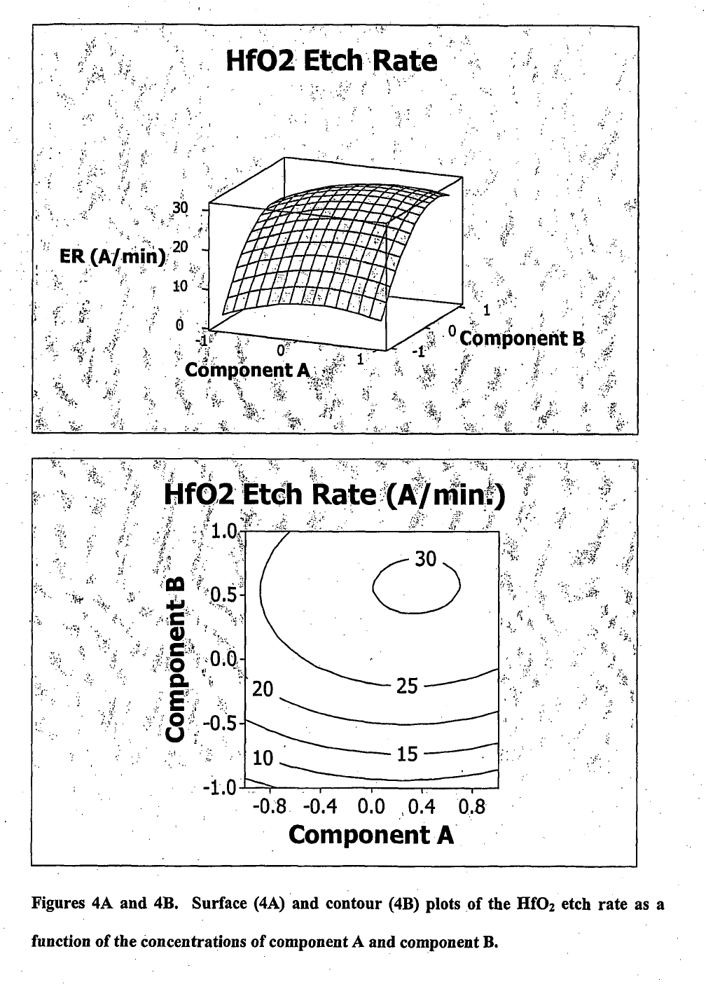

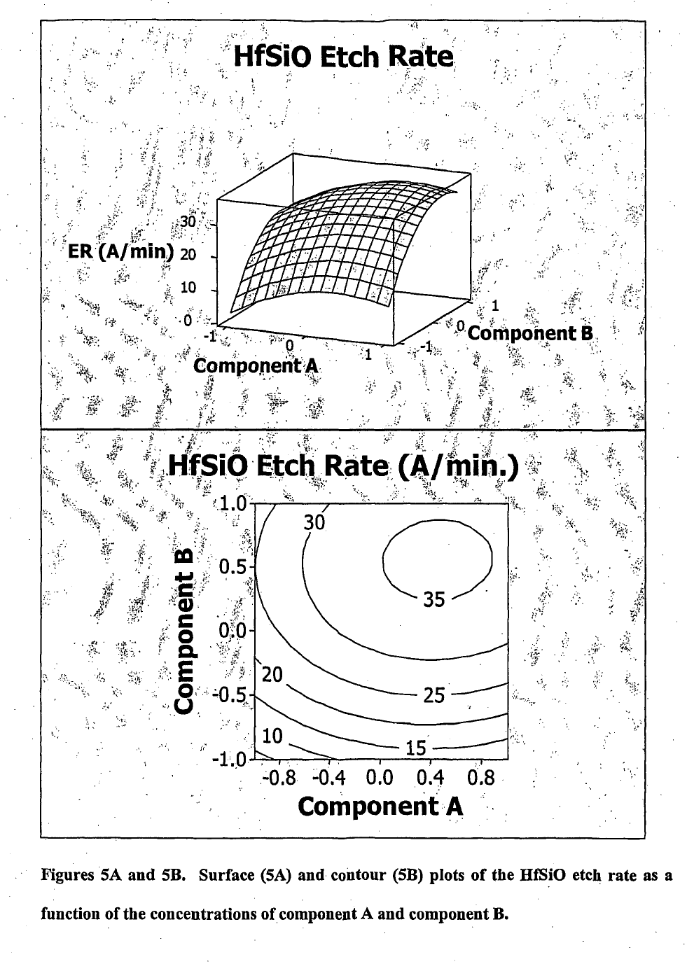

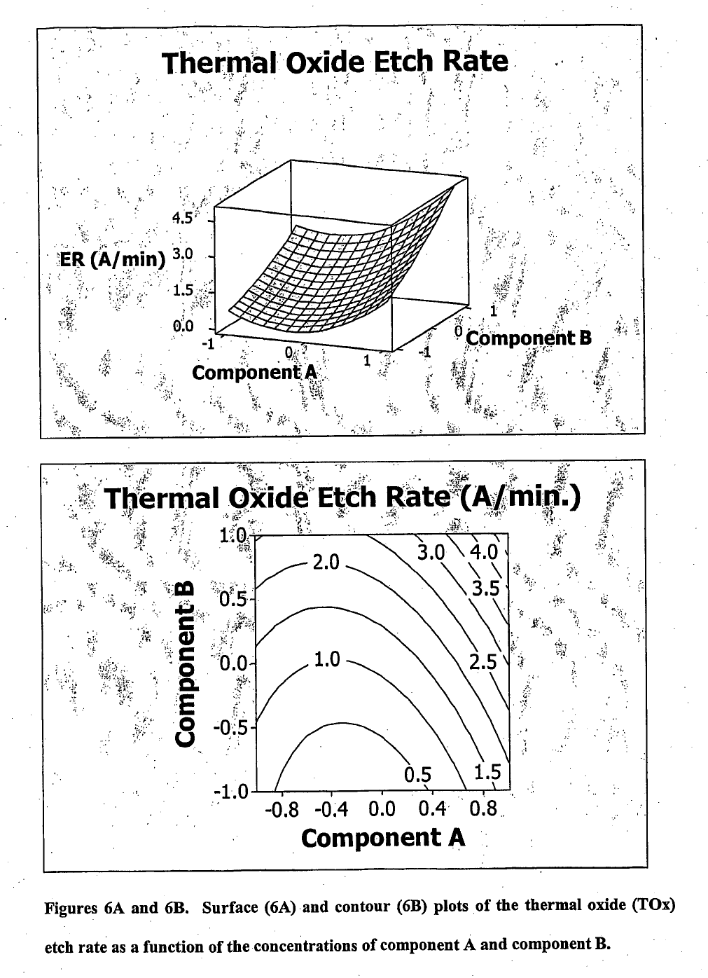

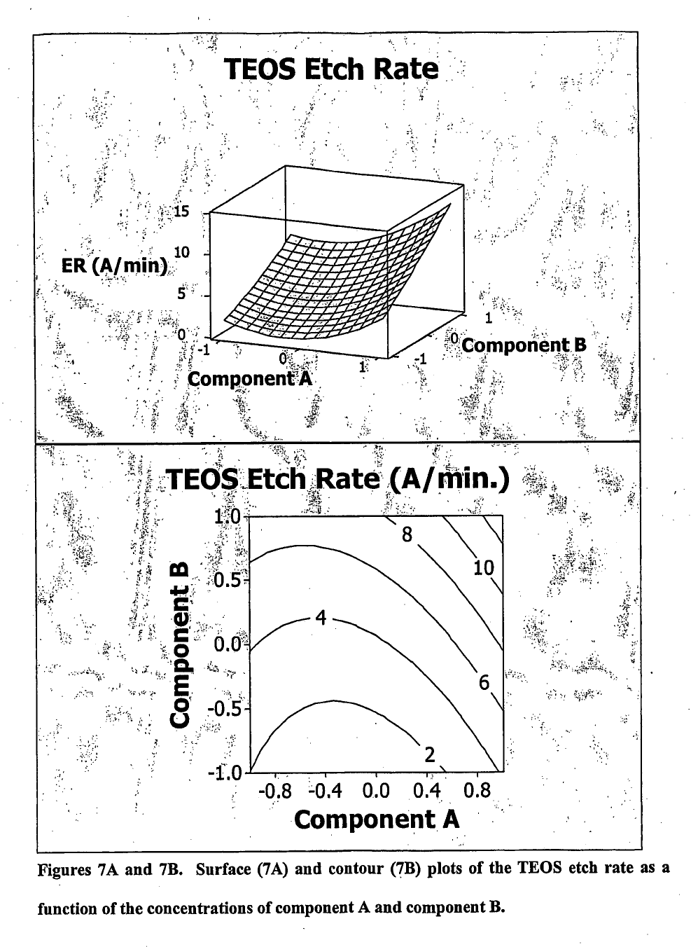

MINITAB 14.1, a statistical analysis computer program (produced by Minitab, Inc.) was utilized to analyze the responses (the etch rates and etch selectivities found in Table 3) as a function of the factor settings (found in Table 2) using response surface methodology. Surface and contour plots of the HfO₂ etch rate as a function of the concentrations of component A and component B are presented in FIGS. 4A and 4B respectively. Surface and contour plots of the HfSiO etch rate as a function of the concentrations of component A and component B are presented in FIGS. 5A and 5B respectively. Surface and contour plots of the TOx etch rate as a function of the concentrations of component A and component B are depicted in FIGS. 6A and 6B respectively. Surface and contour plots of the TEOS etch rate as a function of the concentrations of component A and component B are shown in FIGS. 7A and 7B respectively.

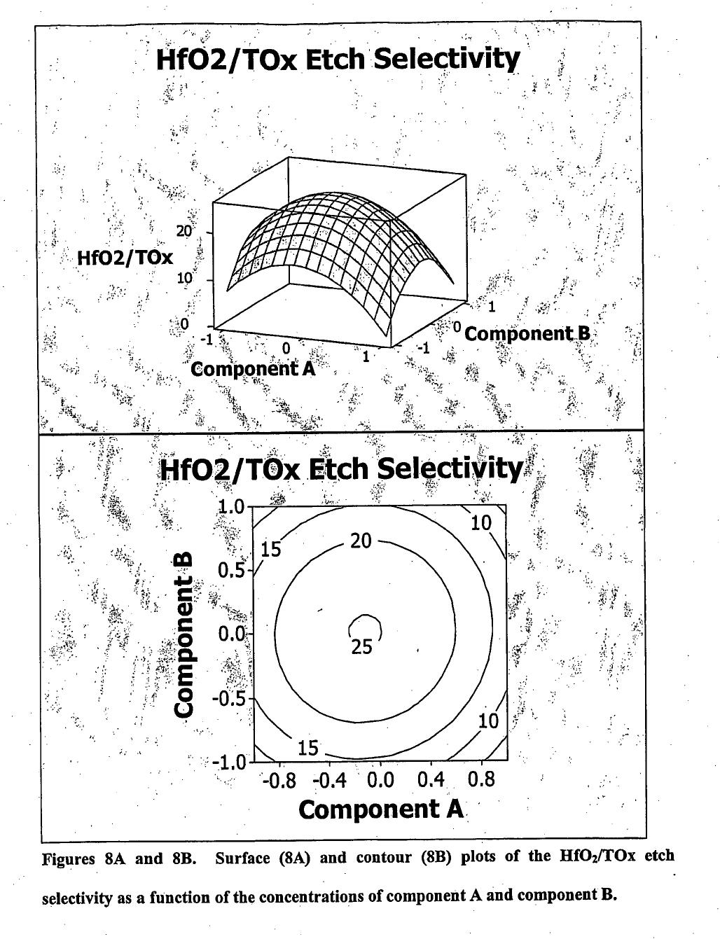

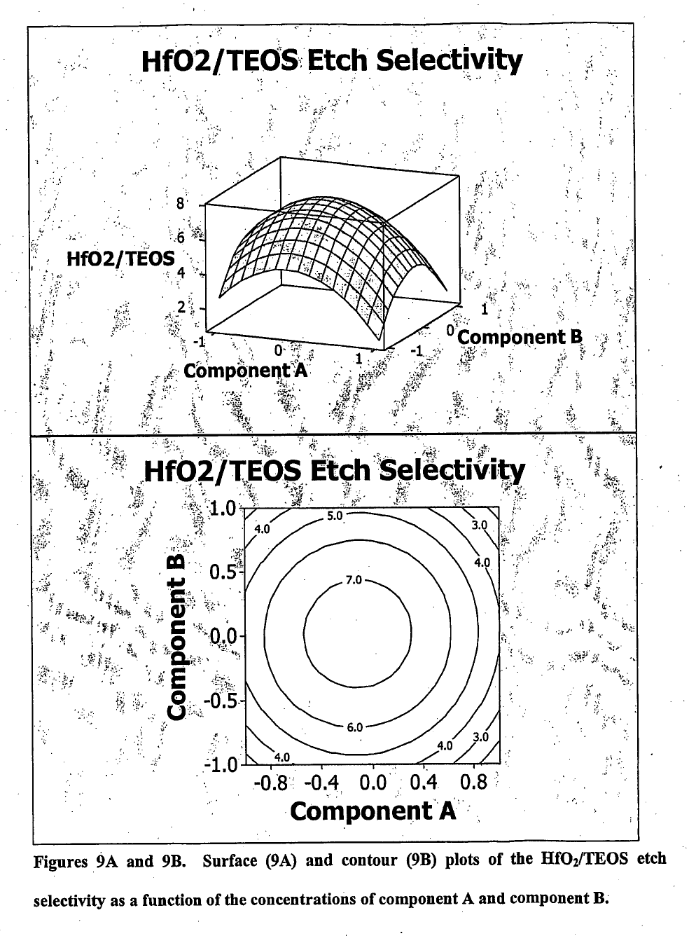

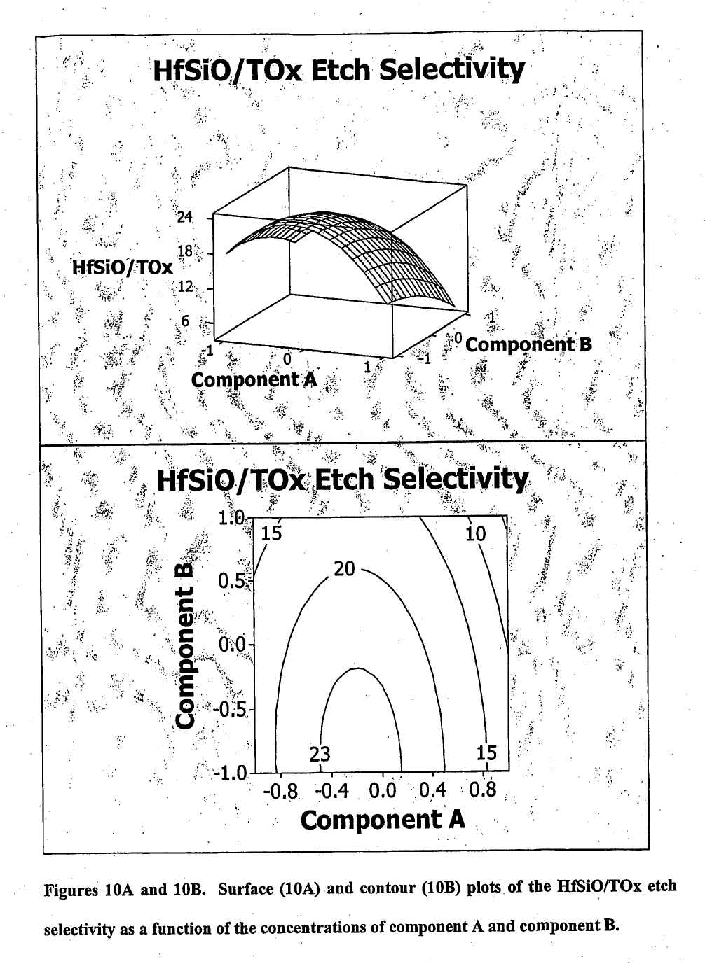

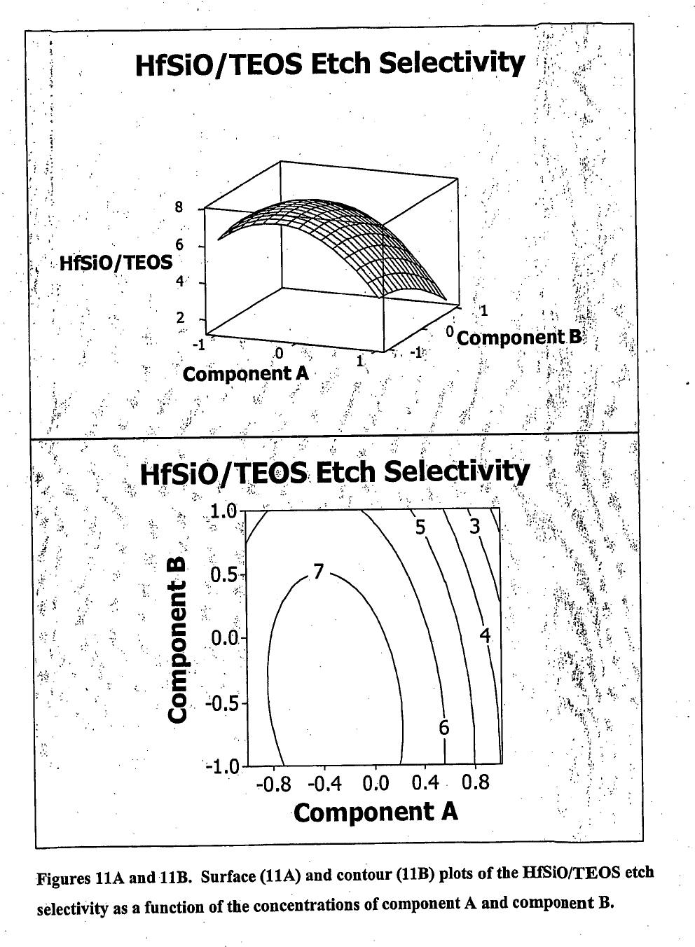

Surface and contour plots of the HfO₂ to TOx (HfO₂/TOx) etch selectivity as a function of the concentrations of component A and component B are presented in FIGS. 8A and 8B respectively. Surface and contour plots of the HfO₂ to TEOS (HfO₂/TEOS) etch selectivity as a function of the concentrations of component A and component B are depicted in FIGS. 9A and 9B respectively. Surface and contour plots of the HfSiO/TOx etch selectivity as a function of the concentrations of component A and component B are presented in FIGS. 10A and 10B respectively. Surface and contour plots of the HfSiO/TEOS etch selectivity as a function of the concentrations of component A and component B are depicted in FIGS. 11A and 11B respectively.

A summary of results is presented in Table 4. Column one contains the important etchant parameters. The parameter values of the HfO₂ etchant are contained in column two. Column three contains the parameter values of the Honeywell HfSiO etchant.

The HfO₂ etch rate is a very strong function of the concentration of component B (FIGS. 4A and 4B). The HfO₂ etch rate, however, is not a strong function of the concentrations of component A. The HfO₂ etch rate, for example, increases by a factor of 5 (from 5 Å/minute to 25 Å/minute) as the concentration of component B increases from the low (−1) setting to the high (+1) setting while the concentration of component A is held constant at the low (−1) setting. On the other hand, the HfO₂ etch rate increases only slightly (from 25 Å/minute to 30 Å/minute) as the concentration of component A increases from the low (−1) setting to the high (+1) setting while the concentration of component B is held constant at the high (+1) setting.

The HfSiO etch rate is a stronger function of the concentration of component B than of component A (FIGS. 5A and 5B). The HfSiO etch rate, for example, increases by a factor of 5 (from 5 Å/minute to 25 Å/minute) as the concentration of component B increases from the low (−1) setting to the high (+1) setting while the concentration of component A is held constant at the low (−1) setting. On the other hand, the HfSiO etch rate increases only slightly (from 25 Å/minute to 35 Å/minute) as the concentration of component A increases from the low (−1) setting to the high (+1) setting while the concentration of component B is held constant at the high (+1) setting.

The TOx etch rate increases slightly with increasing concentrations of component A (FIGS. 6A and 6B). The TOx etch rate, however, is a stronger function of the concentration of component B. The TOx etch rate, for example, increases by approximately a factor of 2 (from 2.5 Å/minute to almost 5 Å/minute) as the concentration of component A increases from the low (−1) setting to the high (+1) setting while the concentration of component B is held constant at the high (+1) setting. On the other hand, the TOx etch rate increases by approximately a factor of 3 (from about 1.5 Å/minute to about 4.5 Å/minute) as the concentration of component B increases from the low (−1) setting to the high (+1) setting while the concentration of component A is held constant at the high (+1) setting.

TABLE 4
Summary of Results

| | | Honeywell |
|---|---|---|
| | Honeywell | HfSiO |
| Parameter | HfO₂ Etchant | Etchant |
| HfO₂ Etch Rate (Å/minute) | 25-30 | 25-30 |
| Maximum HfO₂/TOx Etch Selectivity | 25 | 23 |
| Maximum HfO₂/TEOS Etch Selectivity | 7 | 7 |
| Temperature (° C.) | 20 | 20 |
| Safety | Nonflammable | Nonflammable |
| | Nonvolatile | Nonvolatile |

The TEOS etch rate increases with increasing concentrations of component A as well as component B (FIGS. 7A and 7B). The TEOS etch rate, however, is a stronger function of the concentration of component B than of component A. The TEOS etch rate, for example, increases by a factor of 3 (from 4 Å/minute to 12 Å/minute) as the concentration of component B increases from the low (−1) setting to the high (+1) setting while the concentration of component A is held constant at the high (+1) setting. The TEOS etch rate, however, increases by only a factor of 2 (from 6 Å/minute to 12 Å/minute) as the concentration of component A increases from the low (−1) setting to the high (+1) setting while the concentration of component B is held constant at the high (+1) setting.

The HfO₂/TOx etch selectivity is maximized at a value of 25 when the concentration of component A corresponds to a factor setting of −0.07 and the concentration of component B corresponds to a factor setting of 0.00 (FIGS. 8A and 8B). The HfO₂ etch rate at these factor settings is 27 Å/minute (see FIGS. 4A and 4B).

The HfO₂/TEOS etch selectivity is maximized at a value of 7 when the concentration of component A corresponds to a factor setting of −0.09 and the concentration of component B corresponds to a factor setting of 0.00 (FIGS. 9A and 9B). The HfO₂ etch rate at these factor settings is 27 Å/minute (see FIGS. 4A and 4B). The factor settings resulting in the maximum HfO₂/TEOS etch selectivity (A=−0.09 and B=0.00) are virtually identical to the factor settings resulting in the maximum HfO₂/TOx etch selectivity (A=−0.07 and B=0.00).

The HfSiO/TOx etch selectivity is maximized at a value of 23 when the concentration of component A corresponds to a factor setting of −0.20 and the concentration of component. B corresponds to a factor setting of −0.44 (FIGS. 10A and 10B). The HfSiO etch rate at these factor settings is 25 Å/minute (see FIGS. 5A and 5B). The HfSiO/TEOS etch selectivity is maximized at a value of 7 at these same factor settings of −0.20 and −0.44 for the concentrations of component A and component B respectively (FIGS. 11A and 11B).

Thus, specific embodiments and applications of selective wet etching chemistries and solutions for semiconductor and electronic applications, these solutions manufacture and uses thereof have been disclosed. It should be apparent, however, to those skilled in the art that many more modifications besides those already described are possible without departing from the inventive concepts herein. The inventive subject matter, therefore, is not to be restricted except in the spirit of the disclosure. Moreover, in interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, utilized or combined with other elements, components, or steps that are not expressly referenced.

1. An etchant for selective removal of a high dielectric constant material, comprising:
at least one fluorine-based constituent;
water; and
at least one solvent or solvent mixture.

2. The etchant of claim 1, wherein the high dielectric constant material comprises hafnium, zirconium or a combination thereof.

3. The etchant of claim 2, wherein the high dielectric constant material is hafnium dioxide, hafnium silicate or HfSiON.

4. The etchant of claim 2, wherein the high dielectric constant material is zirconium dioxide or zirconium silicate.

5. The etchant of claim 1, wherein the at least one fluorine-based constituent comprises hydrofluoric acid.

6. The etchant of claim 1, wherein the solvent or solvent mixture comprises propylene carbonate.

7. The etchant of claim 1, wherein the solvent or solvent mixture comprises an aromatic hydrocarbon solvent, an aliphatic hydrocarbon solvent, a cyclic hydrocarbon solvent, a ketone solvent, a carbonate based solvent, a halogenated hydrocarbon solvent, an alcohol solvent, an ester solvent, an ether solvent, an amine solvent or mixtures thereof.

8. The etchant of claim 1, wherein the weight percent of the at least one fluorine-based constituent is between about 0.1 and about 10.

9. The etchant of claim 8, wherein the weight percent of the at least one fluorine-based constituent is between about 0.5 and about 0.85.

10. The etchant of claim 1, wherein the weight percent of the water is between about 0 and about 5 weight percent.

11. The etchant of claim 10, wherein the weight percent of the water is between about 0.1 and about 5.

12. The etchant of claim 1, wherein the etchant further comprises hydrochloric acid.

13. The etchant of claim 12, wherein the weight percent of hydrochloric acid is between about 0.1 and about 2.

14. The etchant of claim 13, wherein the weight percent of HCl is between about 0.15 and about 0.25.

15. A method for producing a wet etching chemistry solution for selective removal of a high dielectric constant material, comprising:
providing at least one fluorine-based constituent;
providing water;
providing at least one solvent or solvent mixture, and
combining the fluorine-based constituent and water into the at least one solvent or solvent mixture to form the wet etching chemistry solution.

16. The method of claim 15, wherein the high dielectric constant material comprises hafnium, zirconium or a combination thereof.

17. The method of claim 16, wherein the high dielectric constant material is hafnium dioxide, hafnium silicate or HfSiON.

18. The method of claim 16, wherein the high dielectric constant material is zirconium dioxide or zirconium silicate.

19. A method of etching a high dielectric constant material, comprising:
providing the etching solution of claim 1;
providing a layered material comprising a high dielectric constant material;
applying the etching solution to the layered material; and
etching at least part of the high dielectric constant material.

20. The method of claim 19, wherein the high dielectric constant material comprises hafnium, zirconium or a combination thereof.

21. An etchant, comprising:
about 0.1 to about 10 weight percent HF;
about 0 to about 5 weight percent of water; and
at least one solvent or solvent mixture.

22. The etchant of claim 21, wherein the solvent or solvent mixture comprises propylene carbonate.

23. The etchant of claim 21, wherein the at least one solvent or solvent mixture comprises an aromatic hydrocarbon solvent, an aliphatic hydrocarbon solvent, a cyclic hydrocarbon solvent, a ketone solvent, a carbonate based solvent, a halogenated hydrocarbon solvent, an alcohol solvent, an ester solvent, an ether solvent, an amine solvent, and mixtures thereof.

24. The etchant of claim 23, wherein the aromatic hydrocarbon solvent comprises toluene, xylene, p-xylene, m-xylene, mesitylene, solvent naphtha H, benzene, 1,2-dimethylbenzene, 1,2,4-trimethylbenzene, isobutylbenzene, ethyltoluene and mixtures thereof.

25. The etchant of claim 23, wherein the aliphatic hydrocarbon solvent comprises pentane, hexane, isohexane, heptane, nonane, octane, dodecane, 2-methylbutane, hexadecane, tridecane, pentadecane, 2,2,4-trimethylpentane, petroleum ethers, solvent naphtha A and mixtures thereof.

26. The etchant of claim 23, wherein the cyclic hydrocarbon solvent comprises cyclopentane, cyclohexane, cycloheptane, cyclooctane, cyclononane, cyclododecane, cyclohexadecane, cyclotridecane, cyclopentadecane and mixtures thereof.

27. The etchant of claim 23, wherein the ketone solvent comprises acetone, diethyl ketone, and methyl ethyl ketone and mixtures thereof.

28. The etchant of claim 23, wherein the halogenated hydrocarbon solvent comprises a chlorinated hydrocarbon solvent, a fluorinated hydrocarbon solvent, and a nitrated hydrocarbon solvent and mixtures thereof.

29. The etchant of claim 21, further comprising about 0 to about 2 weight percent of HCl.

30. The etchant of claim 29, wherein the weight percent of HCl is between 0.15 and 0.25.

31. The etchant of claim 21, wherein the weight percent of HF is between 0.5 and 0.85.

32. The etchant of claim 21, wherein the weight percent of H₂O is between 0.1 and 5.

33. An etchant, comprising:
about 0.1 weight percent to about 10 weight percent HF;
about 0 weight percent to about 2 weight percent HCl;
about 0 weight percent to about 5 weight percent H₂O; and
at least one solvent or solvent mixture.

34. An etchant, comprising:
about 0.1 weight percent to about 10 weight percent HF;
about 0.15 weight percent to about 0.25 weight percent HCl;
about 0.85 weight percent to about 1.25 weight percent H₂O; and
at least one solvent or solvent mixture.

35. A method for etching a dielectric, comprising:
sputter etching a portion of a dielectric film disposed over a substrate; and
applying a wet etchant including a solvent or solvent mixture less polar than water to remove a remaining portion of the dielectric film.

36. The method of claim 35, wherein the method operation of sputter etching a portion of a dielectric film disposed over a substrate includes removing approximately half of the dielectric film.

37. The method of claim 35, wherein the wet etchant includes HF and HCl.

38. The method of claim 37, wherein the wet etchant includes water.

39. The method of claim 35, wherein the solvent less polar than water is propylene carbonate.

40. The method of claim 35, wherein the method operation of sputter etching a portion of a dielectric film disposed over a substrate includes forming an argon based plasma.

41. The method of claim 35, wherein the method operation of applying a wet etchant including a solvent less polar than water to remove a remaining portion of the dielectric film includes maintaining the wet etchant at a temperature between −10 C and 50 C.

42. The method of claim 35, wherein the method operation of applying a wet etchant including a solvent less polar than water to remove a remaining portion of the dielectric film includes maintaining the wet etchant at room temperature.
